(19) United States
(12) Patent Application Publication
(10) Pub. No.: US 2026/0239842 A1
(43) Pub. Date: Aug. 13, 2026

(54) ELECTRONIC DEVICE

(71) Applicant: Samsung Display Co., Ltd., Yongin-si (KR)

(72) Inventors: KI NYENG KANG, Yongin-si (KR); Chanju PARK, Yongin-si (KR); SUNGEUN LEE, Yongin-si (KR); HYOENG-KI KIM, Yongin-si (KR); KEUNKYU SONG, Yongin-si (KR)

(21) Appl. No.: 19/530,044

(22) Filed: Feb. 4, 2026

(30) Foreign Application Priority Data
Feb. 11, 2025 (KR) 10-2025-0017063

(51) Int. Cl. H10K 59/131; H10K 59/122

(52) U.S. Cl. CPC H10K 59/131; H10K 59/122

(57) ABSTRACT

An electronic device includes a base layer defining adjacent first and second areas, a circuit layer above the base layer, first electrodes above the circuit layer and overlapping the first area, a pixel-defining layer above the circuit layer and defining pixel openings exposing portions of the first electrodes, a first connection wire above the pixel-defining layer and configured to receive a first reset voltage, a second connection wire above the pixel-defining layer and configured to receive a second reset voltage, a first common layer above the first electrodes, the first connection wire, and the pixel-defining layer, a first light-emitting layer above the first common layer, a charge generation layer above the first light-emitting layer and the second connection wire, a second light-emitting layer above the charge generation layer, a second common layer above the second light-emitting layer, and a second electrode above the second common layer.

### CROSS-REFERENCE TO RELATED APPLICATION

The present application claims priority to, and the benefit of, Korean Patent Application No. 10-2025-0017063, filed on February 11, 2025, in the Korean Intellectual Property Office, the entire disclosure of which is incorporated herein by reference.

### BACKGROUND

Embodiments of the present disclosure described herein relate to an electronic device having improved display quality.

Each of multimedia electronic devices, such as a TV, a mobile phone, a tablet personal computer (PC), a navigation system, a game console, and the like includes a display device that displays an image. A display device includes a display panel and a driver. The display panel driver includes a scan-driving circuit providing a scan signal to a plurality of scan lines and a data-driving circuit providing a data voltage to data lines.

### SUMMARY

Embodiments of the present disclosure provide an electronic device with improved display quality.

According to one or more embodiments, an electronic device includes a base layer defining a first area, and a second area adjacent to the first area, a circuit layer above the base layer, first electrodes above the circuit layer and overlapping the first area, a pixel-defining layer above the circuit layer and defining pixel openings exposing portions of the first electrodes, a first connection wire above the pixel-defining layer and configured to receive a first reset voltage, a second connection wire above the pixel-defining layer and configured to receive a second reset voltage, a first common layer above the first electrodes, the first connection wire, and the pixel-defining layer, a first light-emitting layer above the first common layer, a charge generation layer above the first light-emitting layer and the second connection wire, a second light-emitting layer above the charge generation layer, a second common layer above the second light-emitting layer, and a second electrode above the second common layer.

The first connection wire may be electrically connected to the first common layer through first contact portions overlapping the first area.

The first contact portions may be respectively between adjacent ones of the first electrodes in plan view.

The first connection wire may be electrically connected to the first common layer through first contact portions having one part overlapping the second area, and another part overlapping the first area.

The second connection wire may be electrically connected to the charge generation layer through a second contact portion overlapping the second area.

The second reset voltage may be lower than the first reset voltage.

The electronic device may further include a first reset transistor configured to be controlled in response to a first reset scan signal and configured to deliver the first reset voltage to the first connection wire, and a second reset transistor configured to be controlled in response to a second reset scan signal and configured to deliver the second reset voltage to the second connection wire.

The first reset transistor and the second reset transistor may be in the second area.

The first reset transistor may be in the first area, wherein the second reset transistor is in the second area.

In a reset period, a first active period of the first reset scan signal may overlap a second active period of the second reset scan signal.

The first connection wire may be configured to receive a third reset voltage that is lower than the first reset voltage.

The electronic device may further include a first reset transistor configured to be controlled in response to a first reset scan signal and configured to deliver the first reset voltage to the first connection wire, a second reset transistor configured to be controlled in response to a second reset scan signal and configured to deliver the second reset voltage to the second connection wire, and a third reset transistor configured to be controlled in response to a third reset scan signal and configured to deliver the third reset voltage to the first connection wire.

In a reset period, a first active period of the first reset scan signal may overlap a second active period of the second reset scan signal, and does not overlap a third active period of the third reset scan signal.

The first reset voltage and the second reset voltage may be externally provided.

According to one or more embodiments, an electronic device includes a display panel defining a display area, and a non-display area adjacent to the display area, the display panel including a base layer, a circuit layer above the base layer, first electrodes above the circuit layer, a pixel-defining layer above the circuit layer and defining pixel openings exposing portions of the first electrodes, a first connection wire above the pixel-defining layer and configured to receive a first reset voltage, a second connection wire above the pixel-defining layer and configured to receive a second reset voltage, a first light-emitting stack above the first electrodes, the first connection wire, and the pixel-defining layer, a charge generation layer above the first light-emitting stack and the second connection wire, a second light-emitting stack above the charge generation layer, and a second electrode above the second light-emitting stack.

The first light-emitting stack may include a first common layer and a first light-emitting layer above the first common layer, wherein the second light-emitting stack includes a second light-emitting layer and a second common layer above the second light-emitting layer, and wherein the first connection wire is electrically connected to the first common layer through first contact portions.

The second connection wire may be electrically connected to the charge generation layer through a second contact portion overlapping the non-display area.

The first connection wire may be configured to receive a third reset voltage that is lower than the first reset voltage.

The display panel may further include a first reset transistor configured to be controlled in response to a first reset scan signal and configured to deliver the first reset voltage to the first connection wire, a second reset transistor configured to be controlled in response to a second reset scan signal and configured to deliver the second reset voltage to the second connection wire, and a third reset transistor configured to be controlled in response to a third reset scan signal and configured to deliver the third reset voltage to the first connection wire.

The electronic device may further include a voltage controller configured to control the first reset voltage and the second reset voltage.

### BRIEF DESCRIPTION OF THE DRAWINGS

The above and other aspects of the present disclosure will become apparent by describing in detail embodiments thereof with reference to the accompanying drawings.

FIG. 1 is a block diagram of an electronic device, according to one or more embodiments of the present disclosure.

FIG. 2 is a schematic diagram of an electronic device, according to various embodiments of the present disclosure.

FIG. 3 is a block diagram of an electronic device, according to one or more embodiments of the present disclosure.

FIG. 4 is an equivalent circuit diagram of a pixel, according to one or more embodiments of the present disclosure.

FIG. 5 is a timing diagram for describing an operation of a pixel, according to one or more embodiments of the present disclosure.

FIG. 6 is a plan view of an electronic device, according to one or more embodiments of the present disclosure.

FIG. 7A is a cross-sectional view illustrating a portion of an electronic device, according to one or more embodiments of the present disclosure.

FIG. 7B is a cross-sectional view illustrating a portion of an electronic device, according to one or more embodiments of the present disclosure.

FIG. 8 is a schematic cross-sectional view of a light-emitting element, according to one or more embodiments of the present disclosure.

FIG. 9 is a cross-sectional view for describing a deposition method of a light-emitting element, according to one or more embodiments of the present disclosure.

FIG. 10 is a schematic diagram for describing a driving aspect of an electronic device, according to one or more embodiments of the present disclosure.

FIG. 11A is a schematic diagram for describing a driving aspect of an electronic device, according to one or more embodiments of the present disclosure.

FIG. 11B is a timing diagram for describing FIG. 11A, according to one or more embodiments of the present disclosure.

FIG. 12A is a schematic diagram for describing a driving aspect of an electronic device, according to one or more embodiments of the present disclosure.

FIG. 12B is a timing diagram for describing FIG. 12A, according to one or more embodiments of the present disclosure.

FIG. 13A is a schematic diagram for describing a driving aspect of an electronic device, according to one or more embodiments of the present disclosure.

FIG. 13B is a timing diagram for describing FIG. 13A, according to one or more embodiments of the present disclosure.

FIG. 13C is a timing diagram for describing FIG. 13A, according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross- hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

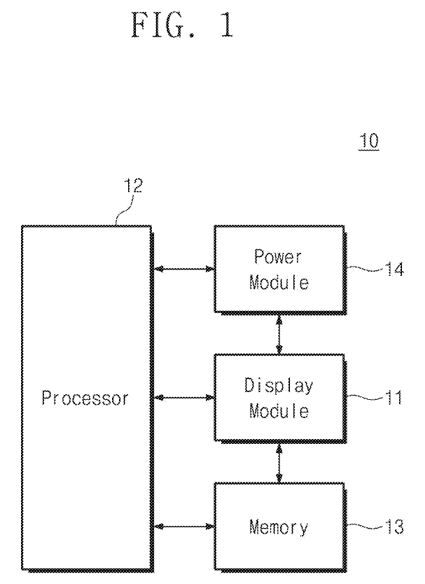

FIG. 1 is a block diagram of an electronic device 10, according to one or more embodiments of the present disclosure.

Referring to FIG. 1, the electronic device 10 according to one or more embodiments may include a display module 11, a processor 12, a memory 13, and a power module 14.

The display module 11 may display an image. The image may include a still image as well as a moving image. The processor 12 may include at least one of a central processing unit (CPU), an application processor (AP), a graphic processing unit (GPU), a communication processor (CP), an image signal processor (ISP), or a controller. The processor 12 may be configured to control an operation of the display module 11.

The memory 13 may store data information suitable for the operation of the processor 12 or the display module 11. When the processor 12 launches an application stored in the memory 13, image data signals and/or input control signals may be delivered to the display module 11, and the display module 11 may process the received signals and may output image information through a display screen.

The power module 14 may include a power supply module, such as a power adapter or a battery device, and a power conversion module that generates power required for the operation of the electronic device 10 by converting power supplied by the power supply module.

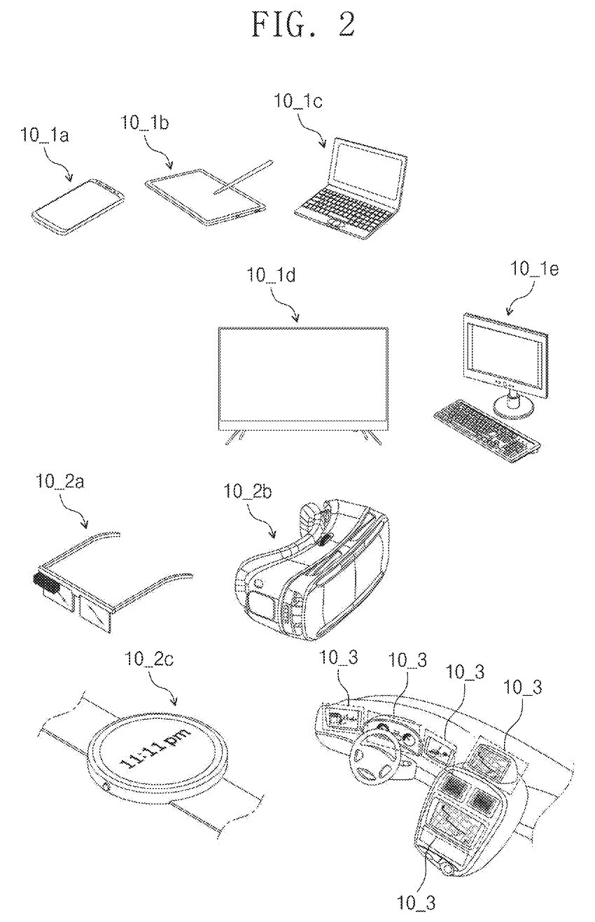

FIG. 2 is a schematic diagram of an electronic device, according to various embodiments of the present disclosure.

Referring to FIG. 2, in addition to electronic devices for displaying images, such as a smart phone 10_1a, a tablet PC 10_1b, a laptop 10_1c, a TV 10_1d, a desk monitor 10_1e, various electronic devices, to which displays are applied, according to embodiments may include wearable electronic devices including display modules, such as smart glasses 10_2a, a head-mounted display 10_2b, a smart watch 10_2c, and automotive electronic devices 10_3 including display modules, such as a dashboard, a center fascia, a center information display (CID) placed on a dashboard, or a room mirror display of a vehicle.

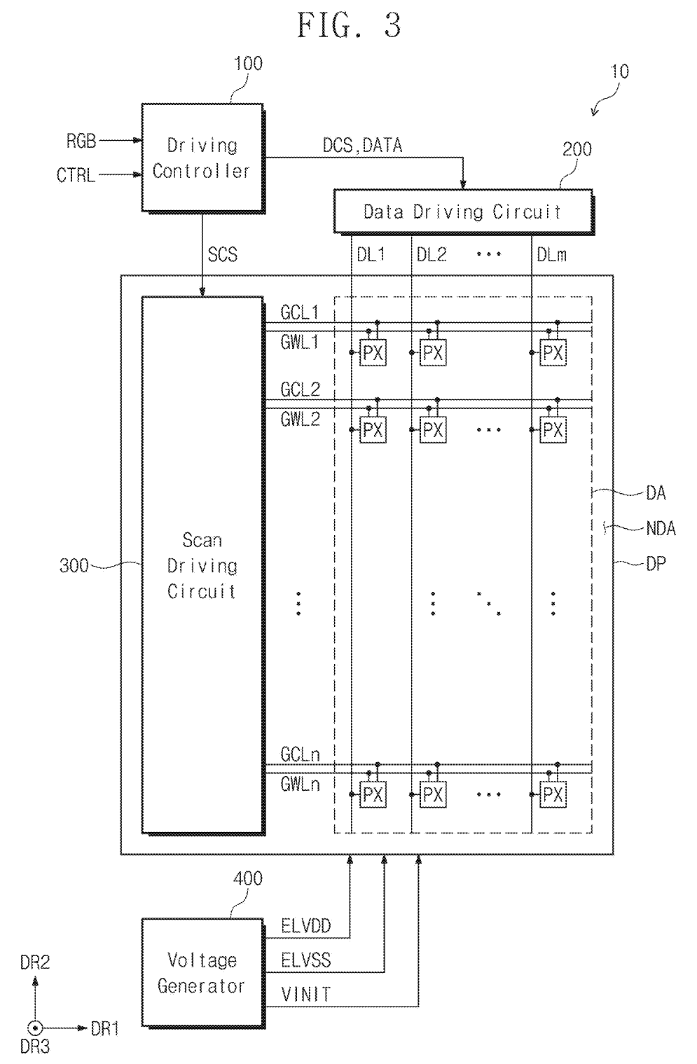

FIG. 3 is a block diagram of the electronic device 10, according to one or more embodiments of the present disclosure.

Referring to FIG. 3, the electronic device 10 may include a driving controller 100, a data-driving circuit 200, a voltage generator 400, and a display panel DP.

The driving controller 100 may receive an input image signal RGB and a control signal CTRL. The driving controller 100 may generate an output image signal DATA by converting a data format of the input image signal RGB so as to be suitable for the interface specification of the data-driving circuit 200. The driving controller 100 may output a data control signal DCS to the data-driving circuit 200 and a scan control signal SCS to a scan-driving circuit 300.

The data-driving circuit 200 may receive the data control signal DCS and the output image signal DATA from the driving controller 100. The data-driving circuit 200 may convert the output image signal DATA into data signals and may output the data signals to a plurality of data lines DL1 to DLm. Each of the data signals may have a voltage level corresponding to a grayscale level of the image signal DATA that is output.

The data-driving circuit 200 may be implemented as an integrated circuit (IC). The data-driving circuit 200 having an IC type may be directly mounted in an area (e.g., a predetermined area) of the display panel DP, or may be mounted on a separate printed circuit board in a chip-on-film (COF) scheme, and then may be electrically connected to the display panel DP. In one or more embodiments, the driving controller 100 and the data-driving circuit 200 may be configured as separate chips, or all of the driving controller 100 and the data-driving circuit 200 may be included within a single chip. In one or more embodiments, the data-driving circuit 200 may be formed in the same process as a pixel circuit of each of pixels PX on the display panel DP.

The voltage generator 400 may generate voltages suitable for the operation of the display panel DP. In one or more embodiments, the voltage generator 400 may generate a first driving voltage ELVDD, a second driving voltage ELVSS, and an initialization voltage VINIT.

The display panel DP may include a display area DA and a non-display area NDA. In one or more embodiments, the display area DA has a rectangular shape, but the present disclosure is not limited thereto. The non-display area NDA may be in a form of a frame surrounding the display area DA.

The display panel DP may further include the scan-driving circuit 300. The pixels PX may be placed in the display area DA, and the scan-driving circuit 300 may be placed in the non-display area NDA. However, one or more embodiments is not limited thereto. At least some of the pixels PX may overlap the scan-driving circuit 300. In this case, at least part of the scan-driving circuit 300 may be located in the display area DA.

The display panel DP may include the plurality of scan lines GCL1 to GCLn and GWL1 to GWLn, the plurality of data lines DL1 to DLm, and the plurality of pixels PX. ‘n’ may be an integer greater than or equal to 2, and ‘m’ may be an integer greater than or equal to 2.

The scan-driving circuit 300 may receive the scan control signal SCS from the driving controller 100. The scan-driving circuit 300 may output scan signals to the scan lines GCL1 to GCLn and GWL1 to GWLn in response to the scan control signal SCS.

The scan-driving circuit 300 may be arranged on a first side of the display panel DP. The scan lines GCL1 to GCLn and GWL1 to GWLn may extend in a first direction DR1 from the scan-driving circuit 300. Each of the scan lines GCL1 to GCLn and GWL1 to GWLn may be spaced apart from each other in a second direction DR2. The data lines DL1 to DLm may extend from the data-driving circuit 200 in the opposite direction of the second direction DR2 and may be spaced apart from each other in the first direction DR1.

The pixels PX may be arranged in the first direction DR1 and the second direction DR2. Each of the pixels PX may be electrically connected to one data line and two scan lines. For example, the pixel PX arranged in the first row and the first column may be electrically connected to the first data line DL1 and the first scan lines GCL1 and GWL1, and the pixel PX arranged in the second row and the first column may be electrically connected to the first data line DL1 and the second scan lines GCL2 and GWL2.

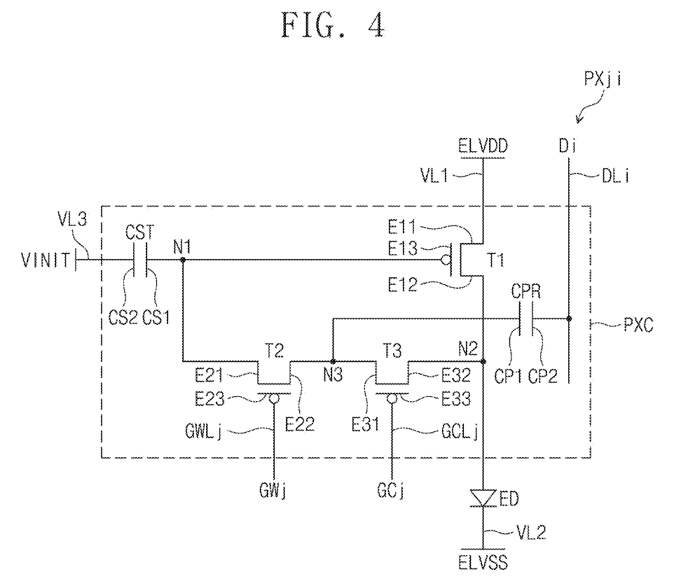

Each of the pixels PX includes a light-emitting element ED (see FIG. 4) and a pixel circuit PXC (see FIG. 4) for controlling the emission of the light-emitting element ED. The pixel circuit PXC may include one or more transistors and one or more capacitors. The scan-driving circuit 300 may include transistors formed through the same process as the pixel circuit PXC.

Each of the pixels PX may receive the first driving voltage ELVDD, the second driving voltage ELVSS, and the initialization voltage VINIT from the voltage generator 400.

FIG. 4 is an equivalent circuit diagram of a pixel PXji, according to one or more embodiments of the present disclosure.

Referring to FIGS. 3 and 4, the equivalent circuit diagram of the pixel PXji connected to the i-th data line DLi among the data lines DL1 to DLm, and the j-th scan lines GCLj and GWLj among the scan lines GCL1 to GCLn and GWL1 to GWLn is shown. Each of the pixels PX shown in FIG. 3 may have the same circuit configuration as the equivalent circuit diagram of the pixel PXji shown in FIG. 4.

The pixel PXji may include the pixel circuit PXC and the light-emitting element ED. The pixel circuit PXC may include first to third transistors T1, T2, and T3 and first to second capacitors CST and CPR. The pixel PXji illustrated in FIG. 4 is only an example, and the circuit configuration of the pixel PXji may be modified and implemented.

Each of the first to third transistors T1, T2, and T3 may be a P-type transistor having a silicon semiconductor layer. However, it is not limited thereto. At least one of the first to third transistors T1, T2, and T3 may be an N-type transistor having an oxide semiconductor layer. The first transistor T1 may also be referred to as a “driving transistor.” The second transistor T2 may also be referred to as a “write transistor.” The third transistor T3 may also be referred to as a “compensation transistor.”

The scan lines GCLj and GWLj may deliver scan signals GCj and GWj, respectively. Hereinafter, the scan lines GCLj and GWLj may be referred to as a “compensation scan line GCLj” and a “write scan line GWLj”, respectively, and the scan signals GCj and GWj may be referred to as a “compensation scan signal GCj” and a “write scan signal GWj”, respectively.

The data line DLi may transmit a data signal Di. The data signal Di may have a voltage level corresponding to the image signal RGB input to the electronic device 10.

First to third driving voltage lines VL1, VL2, and VL3 may deliver the first driving voltage ELVDD, the second driving voltage ELVSS, and the initialization voltage VINIT to the pixel PXji, respectively.

The first transistor T1 may include a first electrode E11 connected to the first driving voltage line VL1, a second electrode E12 connected to a first electrode of the light-emitting element ED, and a gate electrode E13 connected to a first node N1. A portion where the second electrode E12 of the first transistor T1 and the light-emitting element ED are connected to each other may be defined as a second node N2. The first transistor T1 may be turned on or off in response to the voltage of the first node N1.

The second transistor T2 may include a first electrode E21 connected to the first node N1, a second electrode E22 connected to a third node N3, and a gate electrode E23 connected to the write scan line GWLj. The second transistor T2 may be turned on or off in response to the write scan signal GWj received through the write scan line GWLj.

The third transistor T3 may include a first electrode E31 connected to the third node N3, a second electrode E32 connected to the second node N2, and a gate electrode E33 connected to the compensation scan line GCLj. The third transistor T3 may be turned on or off in response to the compensation scan signal GCj received through the compensation scan line GCLj.

The light-emitting element ED may include a first electrode connected to the second node N2 and a second electrode connected to the second driving voltage line VL2. The light-emitting element ED may emit light based on the driving current provided from the first transistor T1. The light-emitting element ED may be an organic light-emitting diode including an organic light-emitting layer, but is not particularly limited thereto.

The first capacitor CPR may be connected between the third node N3 and the data line DLi. A first counter electrode CP1 of the first capacitor CPR may be connected to the third node N3, and a second counter electrode CP2 of the first capacitor CPR may be connected to the data line DLi. The third node N3 may be coupled to the data line DLi, which transmits the data signal Di, by the first capacitor CPR. The first capacitor CPR may be referred to as the “programming capacitor CPR.”

The second capacitor CST may be connected between the first node N1 and the third driving voltage line VL3. A first counter electrode CS1 of the second capacitor CST may be connected to the first node N1, and a second counter electrode CS2 of the second capacitor CST may be connected to the third driving voltage line VL3. The first node N1 may be coupled to the third driving voltage line VL3, which transmits the initialization voltage VINIT, by the second capacitor CST. The second capacitor CST may be referred to as the “storage capacitor CST.”

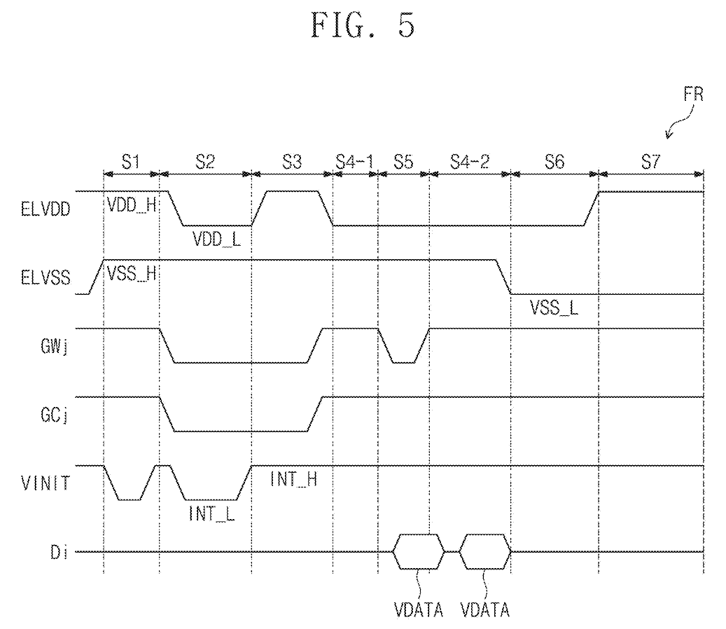

FIG. 5 is a timing diagram for describing an operation of the pixel PXji, according to one or more embodiments of the present disclosure.

Referring to FIGS. 4 and 5, one frame FR of the pixel PXji may include a bias period S1, an initialization period S2, a compensation period S3, a first hold period S4-1, a programming period S5, a second hold period S4-2, a reset period S6, and an emission period S7.

In one or more embodiments of the present disclosure, the voltage level of each of the first driving voltage ELVDD, the second driving voltage ELVSS, and the initialization voltage VINIT may be varied in the one frame FR. The first driving voltage ELVDD may have a low-voltage level VDD_L and a high-voltage level VDD_H higher than the low-voltage level VDD_L. The second driving voltage ELVSS may have a low-voltage level VSS_L and a high-voltage level VSS_H, which is higher than the low-voltage level VSS_L. The initialization voltage VINIT may have a low-voltage level INT_L and a high-voltage level INT_H that is higher than the low-voltage level INT_L.

The bias period S1 may be a period in which the high-voltage level VDD_H of the first driving voltage ELVDD, the high-voltage level VSS_H of the second driving voltage ELVSS, and the low-voltage level INT_L of the initialization voltage VINIT are applied. In the bias period S1, the second scan signal GWj and the third scan signal GCj may have inactive levels. Accordingly, the first transistor T1, the second transistor T2, and the third transistor T3 may be turned off.

The initialization period S2 may be a period in which the low-voltage level VDD_L of the first driving voltage ELVDD, the high-voltage level VSS_H of the second driving voltage ELVSS, and the low-voltage level INT_L of the initialization voltage VINIT are applied. In the initialization period S2, the second scan signal GWj and the third scan signal GCj may have active levels. Accordingly, the first transistor T1 may be turned off, and the second transistor T2 and the third transistor T3 may be turned on. In the initialization period S2, the gate electrode E13 of the first transistor T1 and the anode of the light-emitting element ED may be initialized by the low-voltage level INT_L of the initialization voltage VINIT.

The compensation period S3 may be a period in which the high-voltage level VDD_H of the first driving voltage ELVDD, the high-voltage level VSS_H of the second driving voltage ELVSS, and the high-voltage level INT_H of the initialization voltage VINIT are applied. In the compensation period S3, the second scan signal GWj and the third scan signal GCj may have active levels. Accordingly, the second transistor T2 and the third transistor T3 may be turned on, and thus the first transistor T1 may be diode-connected. Accordingly, the threshold voltage of the first transistor T1 may be compensated.

The first hold period S4-1 may be a period where the low-voltage level VDD_L of the first driving voltage ELVDD, the high-voltage level VSS_H of the second driving voltage ELVSS, and the high-voltage level INT_H of the initialization voltage VINIT are applied. In the first hold period S4-1, the second scan signal GWj and the third scan signal GCj may have inactive levels again. Accordingly, the second transistor T2 and the third transistor T3 may be turned off. In the first hold period S4-1, a state in the compensation period S3 may be maintained. In one or more embodiments, the first hold period S4-1 may be omitted.

The programming period S5 may be a period where the low-voltage level VDD_L of the first driving voltage ELVDD, the high-voltage level VSS_H of the second driving voltage ELVSS, and the high-voltage level INT_H of the initialization voltage VINIT are applied. In the programming period S5, the second scan signal GWj may have an active level, and the third scan signal GCj may have an inactive level. Accordingly, the second transistor T2 may be turned on and the third transistor T3 may be turned off. In the programming period S5, a data voltage VDATA may be written to the first node N1 and the gate electrode E13 of the first transistor T1.

The second hold period S4-2 may be a period where the low-voltage level VDD_L of the first driving voltage ELVDD, the high-voltage level VSS_H of the second driving voltage ELVSS, and the high-voltage level INT_H of the initialization voltage VINIT are applied. In the second hold period S4-2, the second scan signal GWj may have an inactive level again. Accordingly, the second transistor T2 may be turned off. In the second hold period S4-2, a state in the programming period S5 may be maintained. In one or more embodiments, the second hold period S4-2 may be omitted.

The reset period S6 may be a period in which the low-voltage level VDD_L of the first driving voltage ELVDD, the low-voltage level VSS_L of the second driving voltage ELVSS, and the high-voltage level INT_H of the initialization voltage VINIT are applied. Accordingly, the first transistor T1 may be turned on, and the first transistor T1 may be reset by the low-voltage level VDD_L of the first driving voltage ELVDD and the low-voltage level VSS_L of the second driving voltage ELVSS.

The emission period S7 may be a period in which the high-voltage level VDD_H of the first driving voltage ELVDD, the low-voltage level VSS_L of the second driving voltage ELVSS, and the high-voltage level INT_H of the initialization voltage VINIT are applied. Accordingly, the first transistor T1 may be turned on, and a driving current corresponding to the data voltage VDATA, which is obtained by compensating for the threshold voltage of the first transistor T1, may be provided to the light-emitting element ED.

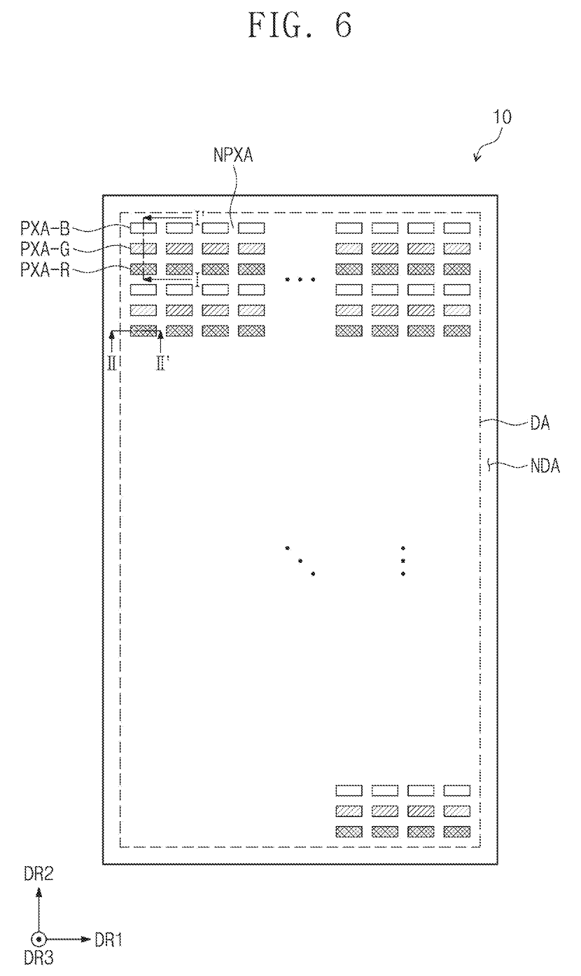

FIG. 6 is a plan view of the electronic device 10, according to one or more embodiments of the present disclosure.

Referring to FIG. 6, the electronic device 10 may include the display area DA, and the non-display area NDA adjacent to the display area DA. The display area DA and the non-display area NDA of the electronic device 10 may correspond to the display area DA and the non-display area NDA of the display panel DP illustrated in FIG. 3, respectively.

The display area DA may include emission areas PXA-R, PXA-G, and PXA-B and a non-emission area NPXA. The non-emission area NPXA may surround the emission areas PXA-R, PXA-G, and PXA-B.

The emission areas PXA-R, PXA-G, and PXA-B may be areas where light generated from the light-emitting elements are emitted, respectively. The emission areas PXA-R, PXA-G, and PXA-B may be spaced apart from each other on a plane.

The emission areas PXA-R, PXA-G, and PXA-B may be split into a plurality of groups depending on the color of light generated from the light-emitting elements. The electronic device 10 according to one or more embodiments illustrated in FIG. 6 illustrates three types of emission areas PXA-R, PXA-G, and PXA-B that emit red light, green light, and blue light. For example, the electronic device 10 according to one or more embodiments may include the red emission area PXA-R, the green emission area PXA-G, and the blue emission area PXA-B, which are distinguished from each other.

The emission areas PXA-R, PXA-G, and PXA-B in the electronic device 10 may be arranged in a stripe form. In one or more embodiments, the plurality of red emission areas PXA-R, the plurality of green emission areas PXA-G, and the plurality of blue emission areas PXA-B may be respectively arranged in the first direction DR1. Moreover, the blue emission area PXA-B, the green emission area PXA-G, and the red emission area PXA-R may be arranged alternately in the second direction DR2.

In FIG. 6, all of the areas of the emission areas PXA-R, PXA-G, and PXA-B are shown as being similar to each other, but one or more embodiments is not limited thereto. The areas of the emission areas PXA-R, PXA-G, and PXA-B may be different from each other depending on the wavelength range of the light being emitted. In the meantime, the areas of the emission areas PXA-R, PXA-G, and PXA-B may mean areas when viewed from above a plane defined by the first direction DR1 and the second direction DR2.

In the meantime, the arrangement of the emission areas PXA-R, PXA-G, and PXA-B is not limited to that illustrated in FIG. 6. The order in which the red emission area PXA-R, the green emission area PXA-G, and the blue emission area PXA-B are arranged may be variously combined and provided depending on the characteristics of the display quality required in the electronic device 10. For example, the array form of the emission areas PXA-R, PXA-G, and PXA-B may have a PENTILE™ array form or a Diamond Pixel™ array form.

Furthermore, the areas of the emission areas PXA-R, PXA-G, and PXA-B may be different from each other. For example, in one or more embodiments, the area of the green emission area PXA-G may be smaller than the area of the blue emission area PXA-B, but one or more embodiments is not limited thereto.

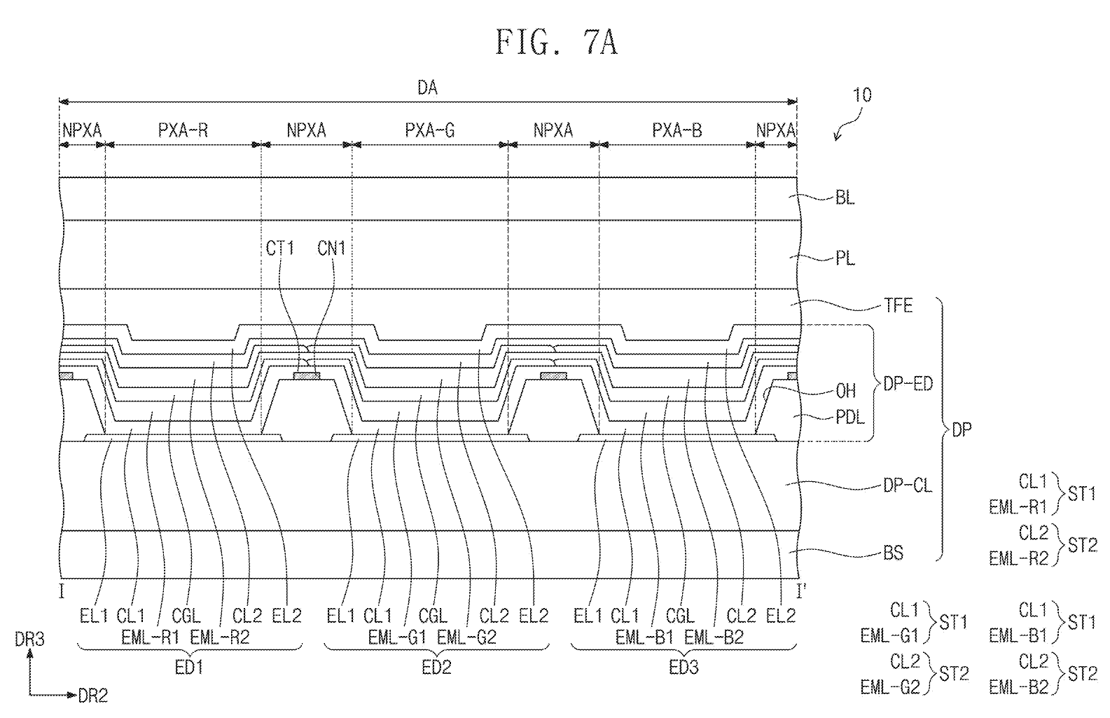

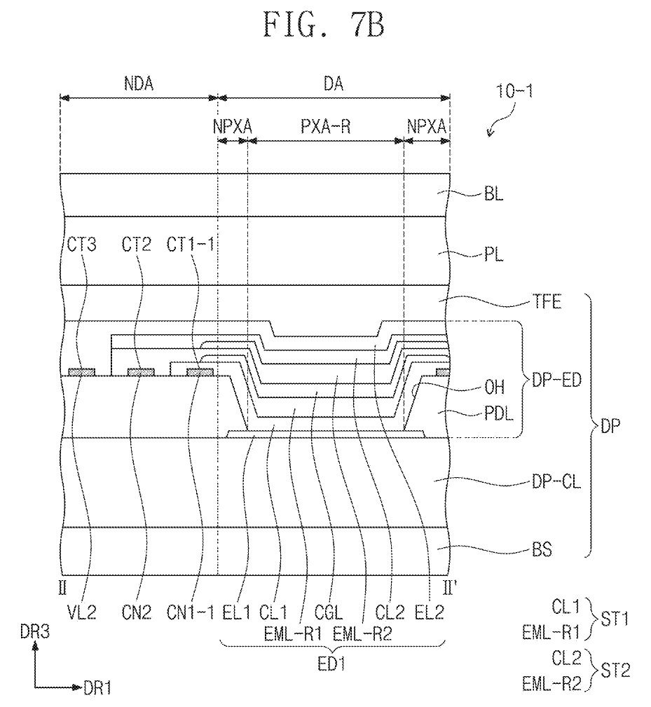

FIG. 7A is a cross-sectional view illustrating a portion of the electronic device 10, according to one or more embodiments of the present disclosure. For example, FIG. 7A is a cross-sectional view taken along the line I-I' of the electronic device 10 illustrated in FIG. 6.

Referring to FIGS. 6 and 7A, the electronic device 10 may include the display panel DP, an optical auxiliary layer PL, and a base substrate BL.

The display panel DP may include a base layer BS, a circuit layer DP-CL, a display element layer DP-ED, and an encapsulation layer TFE.

The base layer BS may provide a base surface on which the circuit layer DP-CL, the display element layer DP-ED, and the encapsulation layer TFE are located. The base layer BS may define a first area, and a second area adjacent to the first area. The first area and the second area of the base layer BS may correspond to the display area DA and the non-display area NDA of the electronic device 10 illustrated in FIG. 6, or the display area DA and the non-display area NDA of the display panel DP illustrated in FIG. 3, respectively.

The base layer BS may be a rigid substrate, or a flexible substrate capable of bending, folding, rolling, or the like. The base layer BS may be a glass substrate, a metal substrate, a polymer substrate, or the like. However, one or more embodiments of the present disclosure is not limited thereto, but the base layer BS may be an inorganic layer, an organic layer, or a composite material layer.

The base layer BS may have a multi-layer structure. For example, the base layer BS may include a first synthetic resin layer, an inorganic layer having a multi-layer structure or a single layer structure, and a second synthetic resin layer located on the inorganic layer having a multi-layer structure or a single layer structure (as used herein, “located on” may mean “above”). Each of the first and second synthetic resin layers may include a polyimide-based resin, and is not particularly limited.

The circuit layer DP-CL may be located on the base layer BS. The circuit layer DP-CL may include a plurality of transistors, in one or more embodiments. Each of the transistors may include a control electrode, an input electrode, and an output electrode. For example, the circuit layer DP-CL may include transistors for driving light-emitting elements ED1, ED2, and ED3 of the display element layer DP-ED.

The display element layer DP-ED may be located on the circuit layer DP-CL. The display element layer DP-ED may include the light-emitting elements ED1, ED2, and ED3, a pixel-defining layer PDL, and a first connection wire CN1.

The emission areas PXA-R, PXA-G, and PXA-B may be defined in each of the light-emitting elements ED1, ED2, and ED3. In one or more embodiments, the light-emitting elements ED1, ED2, and ED3 may emit light in different respective wavelength ranges. For example, in one or more embodiments, the light-emitting elements ED1, ED2, and ED3 may include the first light-emitting element ED1 that emits red light, the second light-emitting element ED2 that emits green light, and the third light-emitting element ED3 that emits blue light. That is, the red emission area PXA-R, the green emission area PXA-G, and the blue emission area PXA-B illustrated in FIG. 6 may correspond to the first light-emitting element ED1, the second light-emitting element ED2, and the third light-emitting element ED3, respectively.

Each of the light-emitting elements ED1, ED2, and ED3 may include an organic luminescent material, an inorganic luminescent material, an organic-inorganic luminescent material, a quantum dot, a quantum rod, a micro-LED, or a nano-LED. Hereinafter, the description will be given under the condition that each of the light-emitting elements ED1, ED2, and ED3 is an organic light-emitting element, but one or more embodiments is not particularly limited thereto.

In one or more embodiments of the present disclosure, each of the light-emitting elements ED1, ED2, and ED3 may include a first electrode EL1, a first light-emitting stack ST1, a charge generation layer CGL, a second light-emitting stack ST2, and a second electrode EL2. Each of the light-emitting elements ED1, ED2, and ED3 may be a light-emitting element having a tandem structure including a plurality of light-emitting stacks ST1 and ST2, each including a light-emitting layer.

The plurality of first electrodes EL1 may be located on the circuit layer DP-CL and may be positioned to overlap the display area DA.

The first light-emitting stack ST1 of the first light-emitting element ED1 may include a first common layer CL1 located on the first electrodes EL1, and a first light-emitting layer EML-R1 located on the first common layer CL1. In one or more embodiments of the present disclosure, the first common layer CL1 may be a hole injection layer.

The second light-emitting stack ST2 of the first light-emitting element ED1 may include a second light-emitting layer EML-R2 and a second common layer CL2. In one or more embodiments of the present disclosure, the second common layer CL2 may be an electron control layer.

The descriptions of the first light-emitting stack ST1 and the second light-emitting stack ST2 of the first light-emitting element ED1 may also be equally applied to the second light-emitting element ED2 and the third light-emitting element ED3. For example, the first light-emitting stack ST1 and the second light-emitting stack ST2 of each of the second light-emitting element ED2 and the third light-emitting element ED3 may include corresponding light-emitting layers.

In one or more embodiments of the present disclosure, the wavelength ranges of light emitted from the light-emitting stacks ST1 and ST2 may be the same as each other. For example, the light emitted from each of the light-emitting stacks ST1 and ST2 of one light-emitting element may be blue light. However, one or more embodiments is not limited thereto. The wavelength ranges of light emitted from the light-emitting stacks ST1 and ST2 may be different from each other. For example, at least one of the light-emitting stacks ST1 or ST2 of one light-emitting element may emit blue light and the other may emit green light. A light-emitting element including the light-emitting stacks ST1 and ST2, which emit light of different wavelength ranges, may emit white light.

The charge generation layer CGL is located on the first light-emitting layers EML-R1, EML-G1, and EML-B1, and may be located between the first light-emitting stack ST1 and the second light-emitting stack ST2. The charge generation layer CGL may generate charges (electrons and holes) by forming a charge-transfer complex through an oxidation-reduction reaction when a voltage is applied. Moreover, the charge generation layer CGL may provide the generated charges to the light-emitting stacks ST1 and ST2. The charge generation layer CGL may double the current efficiency generated by each of the light-emitting stacks ST1 and ST2, and may balance the charges between the first light-emitting stack ST1 and the second light-emitting stack ST2.

The second electrode EL2 may be located on the second light-emitting stack ST2. The second electrode EL2 has an integral shape and may be commonly placed in a plurality of pixels.

FIG. 7A illustrates one or more embodiments in which the first common layer CL1, the charge generation layer CGL, the second common layer CL2, and the second electrode EL2 are provided as common layers throughout the light-emitting elements ED1, ED2, and ED3. However, one or more embodiments is not limited thereto. In one or more embodiments, unlike that illustrated in FIG. 7A, the first common layer CL1, the charge generation layer CGL, and the second common layer CL2 may be patterned and provided. For example, the first light-emitting layers EML-R1, EML-G1, and EML-B1, the first common layer CL1, the charge generation layer CGL, second light-emitting layers EML-R2, EML-G2, and EML-B2, and the second common layer CL2 of the light-emitting elements ED1, ED2, and ED3 may be patterned and provided in an inkjet printing scheme.

The pixel-defining layer PDL may be located on the circuit layer DP-CL. The pixel-defining layer PDL may cover at least part of each of the first electrodes EL1, and a plurality of pixel openings OH exposing portions of the first electrodes EL1 may be defined.

In one or more embodiments of the present disclosure, the first connection wire CN1 may be located on the pixel-defining layer PDL. The first common layer CL1 may be located on the first connection wire CN1. The first connection wire CN1 may be electrically connected to the first common layer CL1 through a plurality of first contact portions CT1. Accordingly, the first common layer CL1 may be located on the first electrodes EL1, the first connection wire CN1, and the pixel-defining layer PDL.

According to one or more embodiments of the present disclosure, the first connection wire CN1 may receive a low voltage. Because the first connection wire CN1 receiving the low voltage is electrically connected to the first common layer CL1, the lateral leakage current leaking between adjacent pixels through the first common layer CL1 may be blocked through the first connection wire CN1. In other words, the lateral leakage current may flow through the first connection wire CN1 receiving the low voltage, and may not leak to adjacent pixels. Meanwhile, the phrase “lateral leakage current” may mean, herein, a current flowing in another direction crossing the third direction DR3 (e.g., the direction in which the image is displayed) other than a current flowing in the third direction DR3, which is a stacking direction of the light- emitting elements ED1, ED2, and ED3. The lateral leakage current may mean the current flowing in a direction parallel to a plane defined by the first direction DR1 and the second direction DR2.

In one or more embodiments of the present disclosure, all of the first contact portions CT1 may overlap the display area DA. In this case, all of the first contact portions CT1 may overlap the non-emission area NPXA of the display area DA.

In one or more embodiments of the present disclosure, the first contact portions CT1 may be placed between two adjacent first electrodes EL1 among the first electrodes EL1. FIG. 7A illustrates that the first contact portions CT1 are placed between two adjacent first electrodes EL1 among the first electrodes EL1, but one or more embodiments is not limited thereto. The first contact portions CT1 may be placed in some of the two adjacent first electrodes EL1 among the first electrodes EL1.

The encapsulation layer TFE may be located on the second electrode EL2 and may cover the light-emitting elements ED1, ED2, and ED3. The encapsulation layer TFE may seal the display element layer DP-ED. The encapsulation layer TFE may be a thin film encapsulation layer. The encapsulation layer TFE may be a single layer or a layer in which a plurality of layers are stacked. The encapsulation layer TFE includes at least one insulating layer. The encapsulation layer TFE according to one or more embodiments may include at least one inorganic film (hereinafter, referred to as an “encapsulation inorganic film”). Moreover, the encapsulation layer TFE according to one or more embodiments of the present disclosure may include at least one organic film (hereinafter, referred to as an “encapsulation organic film”) and at least one encapsulation inorganic film.

The encapsulation inorganic film may protect the display element layer DP-ED from moisture or oxygen. The encapsulation organic film may protect the display element layer DP-ED from foreign objects, such as dust particles. The encapsulation inorganic film may include silicon nitride, silicon oxynitride, silicon oxide, titanium oxide, aluminum oxide, or the like, but is not specifically limited thereto. The encapsulation organic film may include acrylic-based compounds, epoxy-based compounds, and the like. The encapsulating organic film may include a photopolymerizable organic material, but is not particularly limited thereto.

The electronic device 10 according to one or more embodiments may further include a capping layer. The capping layer may be placed between the display element layer DP-ED and the encapsulation layer TFE. The capping layer may be located on the second electrode EL2 and may contact the second electrode EL2. Furthermore, the capping layer may include an organic material.

The optical auxiliary layer PL may be located on the display element layer DP-ED. The optical auxiliary layer PL may include a polarization layer. The optical auxiliary layer PL may be located on the display panel DP to control light reflected from the display panel DP due to external light. In one or more embodiments, the optical auxiliary layer PL may be omitted in the electronic device 10 according to one or more embodiments.

The base substrate BL may be located on the optical auxiliary layer PL. The base substrate BL may be a glass substrate, a metal substrate, a plastic substrate, or the like. However, one or more embodiments is not limited thereto, but the base substrate BL may be an inorganic layer, an organic layer, or a composite material layer. Besides, in one or more embodiments, the base substrate BL may be omitted.

The electronic device 10 according to one or more embodiments may further include a filing layer. The filing layer may be placed between the display element layer DP-ED and the base substrate BL. The charging layer may be an organic layer. The filing layer may comprise at least one of an acrylic-based resin, a silicone-based resin, or an epoxy-based resin.

FIG. 7B is a cross-sectional view illustrating a portion of the electronic device 10, according to one or more embodiments of the present disclosure. For example, FIG. 7B is a cross-sectional view taken along the line II-II' of the electronic device 10 illustrated in FIG. 6. The same reference numerals are assigned to the same configurations as those illustrated in FIG. 7A among configurations illustrated in FIG. 7B, and thus the descriptions thereof are omitted.

Referring to FIGS. 6 and 7B, an electronic device 10-1 may include a first connection wire CN1-1, a second connection wire CN2, and the second driving voltage line VL2.

The first connection wire CN1-1 may be electrically connected to the first common layer CL1 through first contact portions CT1-1. In one or more embodiments of the present disclosure, some of the first contact portions CT1-1 may overlap the display area DA, and the others of the first contact portions CT1-1 may overlap the non-display area NDA.

In one or more embodiments of the present disclosure, the second connection wire CN2 may be located on the pixel-defining layer PDL. The charge generation layer CGL may be located on the second connection wire CN2. The second connection wire CN2 may be electrically connected to the charge generation layer CGL through a second contact portion CT2. Accordingly, the charge generation layer CGL may be located on the first light-emitting layers EML-R1, EML-G1, and EML-B1 and the second connection wire CN2.

According to one or more embodiments of the present disclosure, the second connection wire CN2 may receive a low voltage. Because the second connection wire CN2 receiving the low voltage is electrically connected to the charge generation layer CGL, the lateral leakage current leaking between adjacent pixels through the charge generation layer CGL may be blocked through the second connection wire CN2. In other words, the lateral leakage current may flow through the second connection wire CN2 receiving the low voltage, and may not leak to adjacent pixels.

In one or more embodiments of the present disclosure, the second contact portion CT2 may overlap the non-display area NDA.

The second driving voltage line VL2 may be located on the pixel-defining layer PDL. The second electrode EL2 may be located on the second driving voltage line VL2. The second driving voltage line VL2 is electrically connected to the second electrode EL2 through a third contact portion CT3, and the second driving voltage ELVSS may be delivered to the second electrode EL2.

FIG. 7B illustrates the one second contact portion CT2, but the plurality of second contact portion CT2 may be provided. All of the second contact portions CT2 may be placed in the non-display area NDA.

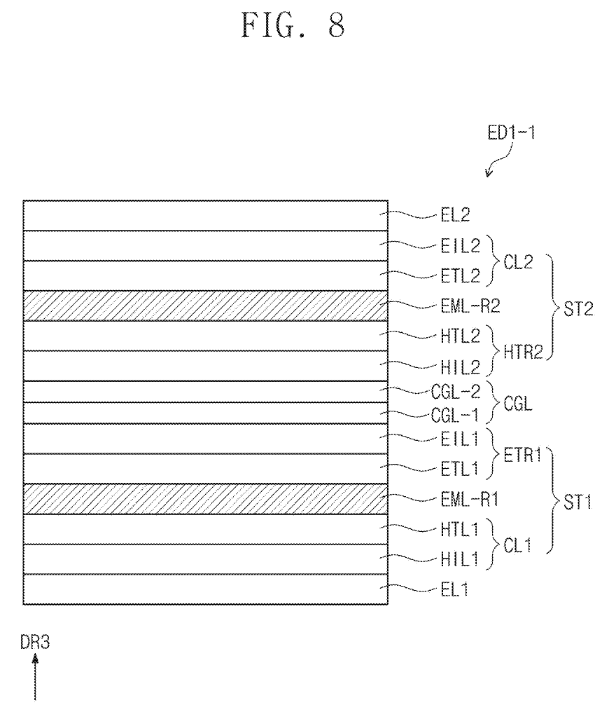

FIG. 8 is a schematic cross-sectional view of a light-emitting element ED1-1, according to one or more embodiments of the present disclosure. The same reference numerals are assigned to the same configurations as those illustrated in FIG. 7A among configurations illustrated in FIG. 8, and thus the descriptions thereof are omitted.

Referring to FIG. 8, the light-emitting element ED1-1 may include the first electrode EL1, the first light-emitting stack ST1, the charge generation layer CGL, the second light-emitting stack ST2, and the second electrode EL2, which are sequentially stacked in the third direction DR3.

The first light-emitting stack ST1 may include the first light-emitting layer EML-R1, the first common layer CL1, and an electron control layer ETR1. In this case, the first common layer CL1 and the electron control layer ETR1 are positioned with the first light-emitting layer EML-R1 therebetween.

The first common layer CL1 may include at least one of a first hole injection layer HIL1 or a first hole transport layer HTL1. The first hole transport layer HTL1 may include at least one of a first hole buffer layer or a first electron-blocking layer. The electron control layer ETR1 may include at least one of a first electron injection layer EIL1 or a first electron transport layer ETL1. The first electron control layer ETR1 may further include a first hole-blocking layer.

The second light-emitting stack ST2 may include the second light-emitting layer EML-R2, a hole control layer HRT2, and the second common layer CL2. In the case, the hole control layer HRT2 and the second common layer CL2 are positioned with the second light-emitting layer EML-R2 therebetween.

The hole control layer HRT2 may include at least one of a second hole injection layer HIL2 or a second hole transport layer HTL2. The second common layer CL2 may include at least one of a second electron injection layer EIL2 or a second electron transport layer ETL2.

The charge generation layer CGL may be placed between the first light-emitting stack ST1 and the second light-emitting stack ST2. In more detail, the charge generation layer CGL may have a layer structure in which a lower charge generation layer CGL-1 and an upper charge generation layer CGL-2 are coupled to each other. The lower charge generation layer CGL-1 may be placed adjacent to the first light-emitting stack ST1, and may be an n-type charge generation layer that provides electrons to the first light-emitting stack ST1. The lower charge generation layer CGL-1 may include an organic compound of the aryl amine group.

The upper charge generation layer CGL-2 may be placed adjacent to the second light-emitting stack ST2 and may be a p-type charge generation layer that provides holes to the second light-emitting stack ST2. The upper charge generation layer CGL-2 may include a charge-generating compound composed of a metal, a metal oxide, a metal carbide, a metal fluoride, or a mixture thereof.

A buffer layer may be further placed between the lower charge generation layer CGL-1 and the upper charge generation layer CGL-2.

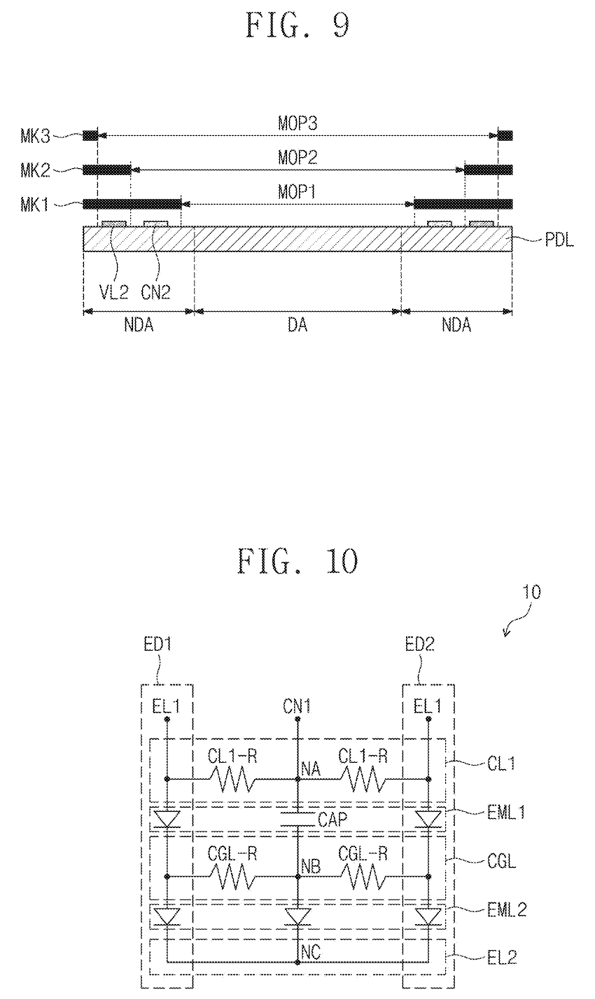

FIG. 9 is a drawing for describing a deposition method of a light-emitting element, according to one or more embodiments of the present disclosure.

Referring to FIGS. 7A, 7B, 8, and 9, layers included in a light-emitting element may be deposited by using three open masks MK1, MK2, and MK3. The open masks MK1, MK2, and MK3 may include the first open mask MK1, the second open mask MK2, and the third open mask MK3.

A first mask opening MOP1 may be defined in the first open mask MK1. A second mask opening MOP2 may be defined in the second open mask MK2. A third mask opening MOP3 may be defined in the third open mask MK3.

In one or more embodiments of the present disclosure, the first mask opening MOP1 may overlap the entire display area DA and a part of the non-display area NDA. The first mask opening MOP1 may overlap the first connection wire CN1, but may not overlap the second connection wire CN2 and the second driving voltage line VL2. The second mask opening MOP2 may overlap the first mask opening MOP1 and the second connection wire CN2. The third mask opening MOP3 may overlap the second mask opening MOP2 and the second driving voltage line VL2.

In one or more embodiments of the present disclosure, at least part of the first light-emitting stack ST1 may be deposited by using the first open mask MK1. For example, at least part of the first light-emitting stack ST1 may include the rest of the first light-emitting stack ST1 illustrated in FIG. 8, excluding the first light-emitting layer EML-R1. The first common layer CL1 may be deposited to cover the first connection wire CN1.

At least part of the charge generation layer CGL and the second light-emitting stack ST2 may be deposited by using the second open mask MK2. For example, at least part of the second light-emitting stack ST2 may include the rest of the second light-emitting stack ST2 illustrated in FIG. 8, excluding the second light-emitting layer EML-R2. The charge generation layer CGL may be deposited to cover the second connection wire CN2.

In one or more embodiments of the present disclosure, the first light-emitting layers EML-R1, EML-G1, and EML-B1 may be placed to correspond to the pixel openings OH, respectively, and the second light-emitting layers EML-R2, EML-G2, and EML-B2 may be placed to correspond to the pixel openings OH, respectively. That is, the first light-emitting layers EML-R1, EML-G1, and EML-B1 may be formed separately in each pixel, and the second light-emitting layers EML-R2, EML-G2, and EML-B2 may be formed separately in each pixel. Accordingly, the first light-emitting layers EML-R1, EML-G1, and EML-B1 and the second light-emitting layers EML-R2, EML-G2, and EML-B2 may be formed in an inkjet process or by using a fine metal mask. However, one or more embodiments is not particularly limited thereto. For example, the first light-emitting layers EML-R1, EML-G1, and EML-B1 may be formed during a process by using the first open mask MK1, and the second light-emitting layers EML-R2, EML-G2, and EML-B2 may be formed during a process by using the second open mask MK2. In this case, the display panel DP (see FIG. 3) may further include a light conversion pattern layer for converting light, which is provided to a common layer, and which is provided from the first light-emitting layers EML-R1, EML-G1, and EML-B1 and the second light-emitting layers EML-R2, EML-G2, and EML-B2, or a color filter layer for transmitting light of a corresponding wavelength band.

In one or more embodiments of the present disclosure, the second electrode EL2 may be deposited by using the third open mask MK3. The second electrode EL2 may be deposited to cover the second driving voltage line VL2.

FIG. 10 is a schematic diagram for describing a driving aspect of the electronic device 10, according to one or more embodiments of the present disclosure. The same reference numerals are assigned to the same configurations as those illustrated in FIGS. 7A and 7B among configurations illustrated in FIG. 10, and thus the descriptions thereof are omitted.

In FIG. 10, to help understanding, the first and second light-emitting layers EML-R1 and EML-R2 of the first light-emitting element ED1 and the first and second light-emitting layers EML-G1 and EML-G2 of the second light-emitting element ED2 illustrated in FIG. 7A are schematically illustrated as diodes.

In FIG. 10, the first common layer CL1, the charge generation layer CGL, and the second electrode EL2 are respectively schematically illustrated as a single line.

A first light-emitting layer group EML1 is placed between the first common layer CL1 and the charge generation layer CGL, and a second light-emitting layer group EML2 is placed between the charge generation layer CGL and the second electrode EL2. The first light-emitting layer group EML1 includes the first light-emitting layer EML-R1 of the first light-emitting element ED1 and the first light-emitting layer EML-G1 of the second light-emitting element ED2. The second light-emitting layer group EML2 includes the second light-emitting layer EML-R2 of the first light-emitting element ED1 and the second light-emitting layer EML-G2 of the second light-emitting element ED2.

Referring to FIGS. 7A, 7B, and 10, resistors CL1-R and CGL-R in the first direction DR1 are present in each of the first common layer CL1 and the charge generation layer CGL. In one or more embodiments, a portion of the first common layer CL1 and the charge generation layer CGL may be short-circuited, or may have increased resistance. For example, in the first common layer CL1 and the charge generation layer CGL, a protruding structure or a concave depression in which the short-circuiting or the resistance of the resistor CL1-R or CGL-R increases may be provided to the pixel-defining layer PDL. For this reason, the resistance of the resistor CL1-R of the first common layer CL1 and the resistance of the resistor CGL-R of the charge generation layer CGL may increase.

In one or more embodiments of the present disclosure, the first connection wire CN1 may be provided with a low voltage. In this case, the first connection wire CN1, the charge generation layer CGL, and a portion of the first light-emitting layer group EML1 between the first connection wire CN1 and the charge generation layer CGL may function as a capacitor (hereinafter, a parasitic capacitor CAP). Accordingly, the parasitic capacitor CAP is charged by the lateral leakage current through the charge generation layer CGL, and the lateral leakage current moving to adjacent pixels may be reduced or prevented until the parasitic capacitor CAP is charged. For example, because the parasitic capacitor CAP is charged by the lateral leakage current flowing from the first light-emitting element ED1, which is emitting light, through a second connection node NB to the second light-emitting element ED2, which is not emitting light, the lateral leakage current flowing from the first light-emitting element ED1 to the second light-emitting element ED2 may be blocked, thereby reducing or preventing contrast distortion caused by the lateral leakage current.

In one or more embodiments of the present disclosure, the first electrode EL1 of the first light-emitting element ED1 and the first electrode EL1 of the second light-emitting element ED2 may be electrically connected to the first common layer CL1. Accordingly, the first electrode EL1 of the first light-emitting element ED1 may be electrically connected to the first electrode EL1 of the second light-emitting element ED2 through the first common layer CL1. Accordingly, the low voltage may be supplied to the first electrode EL1 of the first light-emitting element ED1 and to the first electrode EL1 of the second light-emitting element ED2 through the first connection wire CN1. For this reason, at the timing when the first and second light-emitting elements ED1 and ED2 do not emit light, the first electrode EL1 of the first light-emitting element ED1 and the first electrode EL1 of the second light-emitting element ED2 may be reset.

In addition, according to one or more embodiments of the present disclosure, at the timing when the first and second light-emitting elements ED1 and ED2 emit light, the lateral leakage current flowing through the first common layer CL1 via the first connection node NA may be reduced or prevented by the low voltage provided through the first connection wire CN1.

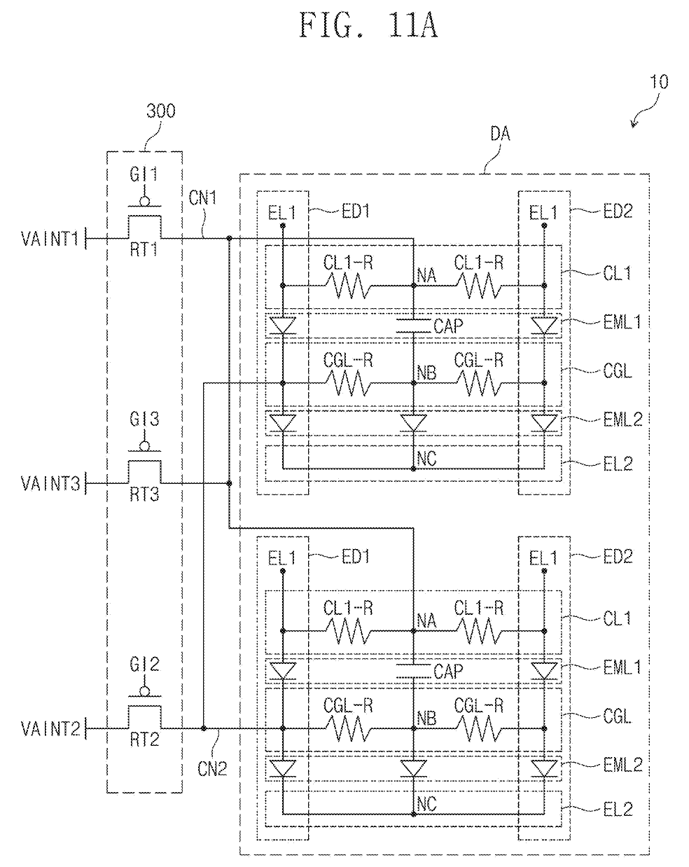

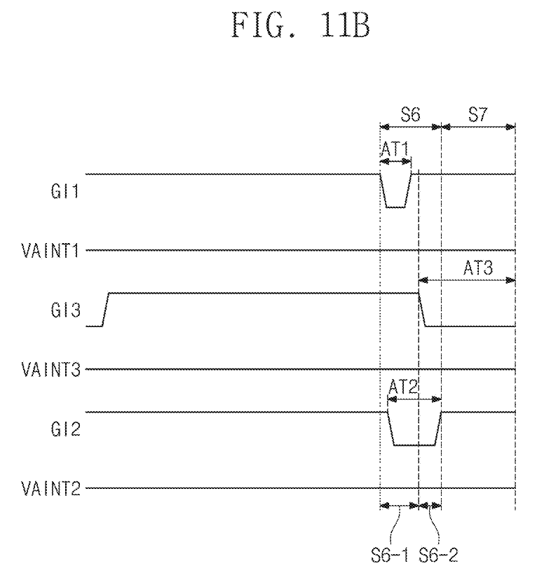

FIG. 11A is a schematic diagram for describing a driving aspect of the electronic device 10, according to one or more embodiments of the present disclosure. FIG. 11B is a timing diagram for describing FIG. 11A, according to one or more embodiments of the present disclosure. The same reference numerals are assigned to the same configurations as those illustrated in FIG. 10 among configurations illustrated in FIG. 11A, and thus the descriptions thereof are omitted.

Referring to FIGS. 5, 10, 11A, and 11B, the electronic device 10 may include a first reset transistor RT1, a second reset transistor RT2, and a third reset transistor RT3.

In one or more embodiments of the present disclosure, the first reset transistor RT1 may be controlled in response to a first reset scan signal GI1, and may deliver a first reset voltage VAINT1 to the first connection wire CN1. The second reset transistor RT2 may be controlled in response to a second reset scan signal GI2, and may deliver a second reset voltage VAINT2 to the second connection wire CN2. The third reset transistor RT3 may be controlled in response to a third reset scan signal GI3, and may deliver a third reset voltage VAINT3 to the first connection wire CN1.

The reset period S6 may be defined as a first reset period S6-1 and a second reset period S6-2.

According to one or more embodiments of the present disclosure, in the first reset period S6-1, the first reset scan signal GI1 may have an active level, and the first reset transistor RT1 may be turned on in response to the first reset scan signal GI1. The first reset voltage VAINT1 may be delivered to the first connection wire CN1 through the first reset transistor RT1. In one or more embodiments, the first reset voltage VAINT1 may be lower than the voltage at which each of the light-emitting elements ED1 and ED2 emits light. Accordingly, before the emission period S7, the voltage of the first common layer CL1 and the voltage of the first electrodes EL1 may be reset by the first reset voltage VAINT1.

According to one or more embodiments of the present disclosure, in the second reset period S6-2 and the emission period S7, the third reset scan signal GI3 may have an active level, and the third reset transistor RT3 may be turned on in response to the third reset scan signal GI3. The third reset voltage VAINT3 may be delivered to the first connection wire CN1 through the third reset transistor RT3. In one or more embodiments, the third reset voltage VAINT3 may be different from the first reset voltage VAINT1, and the third reset voltage VAINT3 may be lower than the first reset voltage VAINT1. Accordingly, in the emission period S7, a reverse bias may be applied between the first electrodes EL1 and the second electrode EL2 by the third reset voltage VAINT3. In this case, the third reset voltage VAINT3 may be lower than the voltage of the second electrode EL2. Accordingly, compared to a case where the first reset voltage VAINT1 is applied, a stronger reverse bias may be applied between the first electrodes EL1 and the second electrode EL2.

According to one or more embodiments of the present disclosure, in the reset period S6, the second reset scan signal GI2 may have an active level, and the second reset transistor RT2 may be turned on in response to the second reset scan signal GI2. The second reset voltage VAINT2 may be delivered to the second connection wire CN2 through the second reset transistor RT2. In one or more embodiments, the second reset voltage VAINT2 may be different from the first reset voltage VAINT1, and the second reset voltage VAINT2 may be lower than the first reset voltage VAINT1. In one or more embodiments, each of the first reset voltage VAINT1 and the second reset voltage VAINT2 may be lower than the voltage for emitting light of the light-emitting elements ED1 and ED2. Accordingly, before the emission period S7, the voltage of the charge generation layer CGL may be reset by the second reset voltage VAINT2. During the emission period S7, because a reverse bias is applied between the first electrodes EL1 and the second electrode EL2, the lateral leakage current through the charge generation layer CGL may be reduced or prevented from moving to the adjacent pixels, and the lateral leakage current through the first common layer CL1 may be reduced or prevented from moving to adjacent pixels by the first reset voltage VAINT1 applied to the first common layer CL1. As a result, the display quality of the electronic device 10 may be improved by reducing or preventing contrast distortion caused by the lateral leakage current.

According to one or more embodiments of the present disclosure, in the reset period S6, a first active period AT1 of the first reset scan signal GI1, and a second active period AT2 of the second reset scan signal GI2, may overlap a third active period AT3 of the third reset scan signal GI3. In one or more embodiments, in the reset period S6, the first active period AT1 may not overlap the third active period AT3.

The first reset transistor RT1 and the second reset transistor RT2 may be placed within the scan-driving circuit 300 located in the non-display area NDA (see FIG. 3). However, one or more embodiments is not limited thereto. The first reset transistor RT1 may be placed in the display area DA, and the second reset transistor RT2 may be placed in the scan-driving circuit 300. Moreover, the first reset transistor RT1 and the second reset transistor RT2 may be placed within the non-display area NDA (see FIG. 3) other than the scan-driving circuit 300.

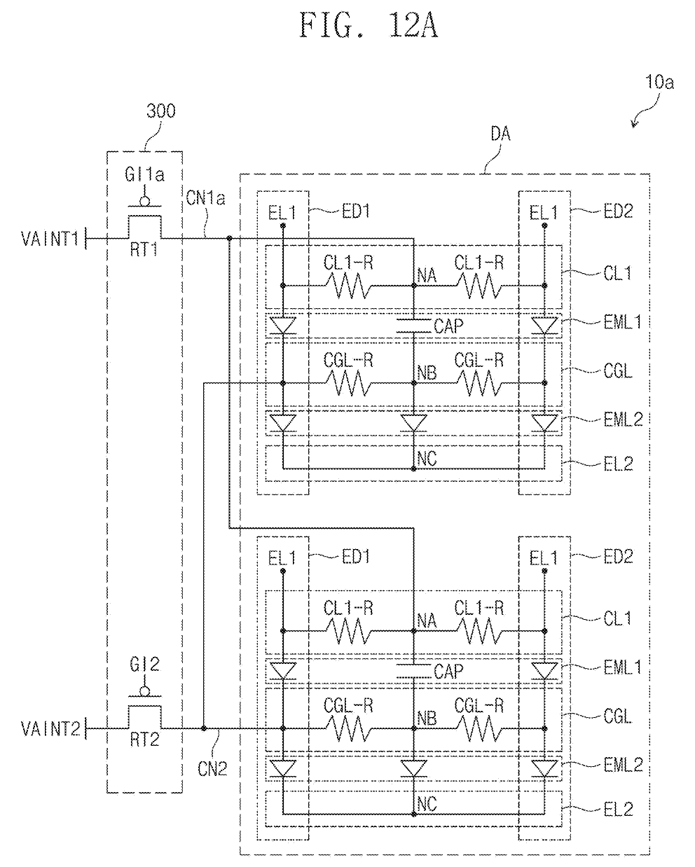

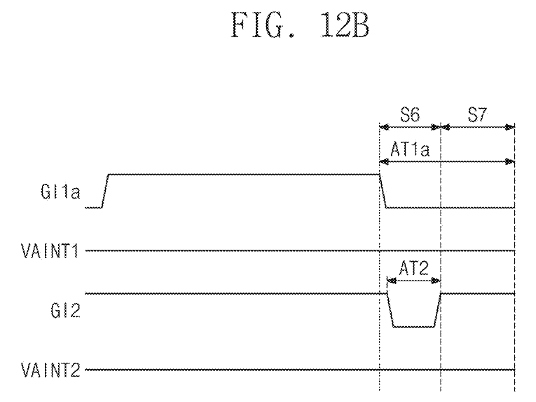

FIG. 12A is a schematic diagram for describing a driving aspect of an electronic device 10a, according to one or more embodiments of the present disclosure. FIG. 12B is a timing diagram for describing FIG. 12A, according to one or more embodiments of the present disclosure. The same reference numerals are assigned to the same configurations as those illustrated in FIG. 10 among configurations illustrated in FIG. 12A, and thus the descriptions thereof are omitted. The description of FIG. 11A is equally applied to one or more embodiments of FIG. 12A, and the differences from FIG. 11A are mainly described.

Referring to FIGS. 5, 10, 12A, and 12B, the electronic device 10a may include a first reset transistor RT1 and the second reset transistor RT2.

In one or more embodiments of the present disclosure, the first reset transistor RT1 may be controlled in response to a first reset scan signal GI1a, and may deliver the first reset voltage VAINT1 to a first connection wire CN1a.

According to one or more embodiments of the present disclosure, in the reset period S6 and the emission period S7, the first reset scan signal GI1a may have an active level, and the first reset transistor RT1 may be turned on in response to the first reset scan signal GI1a. The first reset voltage VAINT1 may be delivered to the first connection wire CN1a through the first reset transistor RT1. In one or more embodiments, the first reset voltage VAINT1 may be lower than the voltage at which each of the light-emitting elements ED1 and ED2 emits light. Accordingly, in the reset period S6, the voltage of the first common layer CL1 and the voltage of the first electrodes EL1 are reset by the first reset voltage VAINT1, and in the emission period S7, a reverse bias may be applied between the first electrodes EL1 and the second electrode EL2 by the first reset voltage VAINT1.

According to one or more embodiments of the present disclosure, in the reset period S6, a first active period AT1a of the first reset scan signal GI1a may overlap the second active period AT2 of the second reset scan signal GI2.

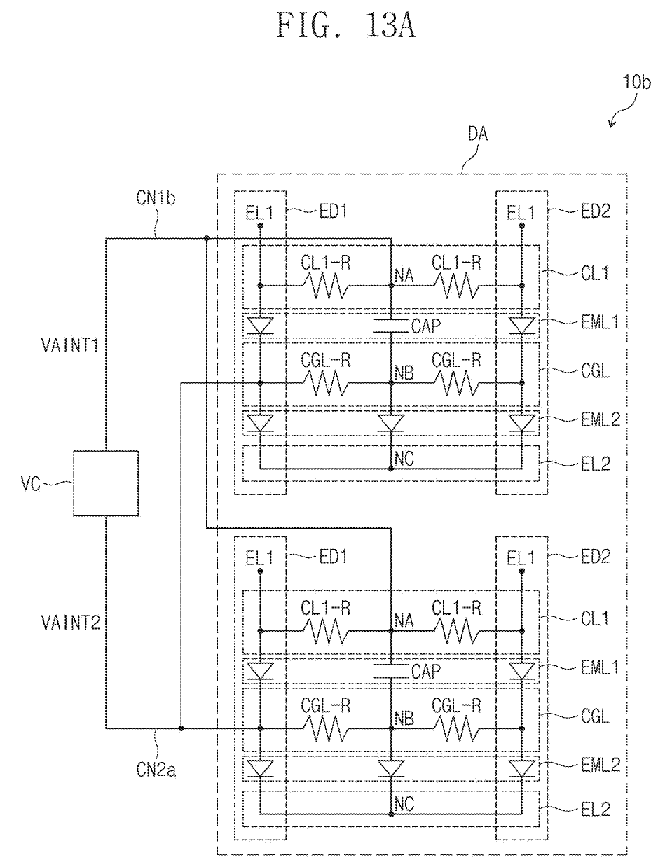

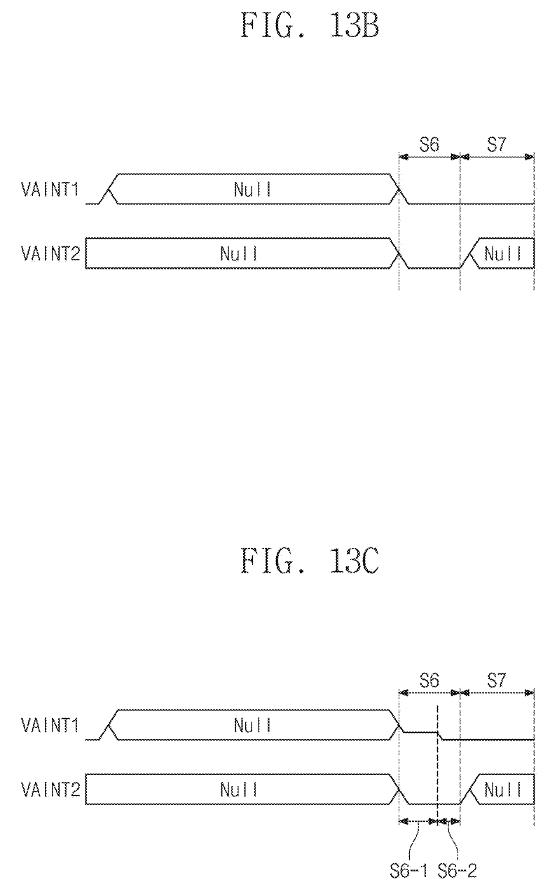

FIG. 13A is a schematic diagram for describing a driving aspect of an electronic device 10b, according to one or more embodiments of the present disclosure. FIG. 13B is a timing diagram for describing FIG. 13A, according to one or more embodiments of the present disclosure. The same reference numerals are assigned to the same configurations as those illustrated in FIG. 10 among configurations illustrated in FIG. 13A, and thus the descriptions thereof are omitted. The description of FIG. 11A is equally applied to one or more embodiments of FIG. 13A, and the differences from FIG. 11A are mainly described.

Referring to FIGS. 5, 10, 13A, and 13B, the electronic device 10b may include a voltage controller VC.

In one or more embodiments of the present disclosure, the voltage controller VC may control the first reset voltage VAINT1 and the second reset voltage VAINT2. For example, the voltage controller VC may control the timing of each of the first reset voltage VAINT1 and the second reset voltage VAINT2. Under the control of the voltage controller VC, the first reset voltage VAINT1 may be output in the reset period S6 and the emission period S7, and the second reset voltage VAINT2 may be output in the reset period S6. A first connection wire CN1b may receive the first reset voltage VAINT1, and a second connection wire CN2a may receive the second reset voltage VAINT2.

In one or more embodiments of the present disclosure, the voltage controller VC may be included in the voltage generator 400 (see FIG. 3). However, one or more embodiments is not limited thereto. The voltage controller VC may be provided as a separate chip from the voltage generator 400.

In one or more embodiments of the present disclosure, the voltage controller VC may be electrically connected to the display panel DP (see FIG. 3). Accordingly, even when there is insufficient space to place transistors for controlling the first reset voltage VAINT1 and the second reset voltage VAINT2 within the display panel DP (see FIG. 3), the timing of each of the first reset voltage VAINT1 and the second reset voltage VAINT2 may be controlled by the voltage controller VC placed outside the display panel DP (see FIG. 3).

FIG. 13C is a timing diagram for describing FIG. 13A, according to one or more embodiments of the present disclosure. The description of FIG. 13B is equally applied to one or more embodiments of FIG. 13C, and the differences from FIG. 13B are mainly described.

Referring to FIGS. 5, 10, 13A, and 13C, the reset period S6 may be defined as the first reset period S6-1 and the second reset period S6-2. Under the control of the voltage controller VC, the first reset voltage VAINT1 may be output in the first reset period S6-1, the second reset period S6-2, and the emission period S7, and the second reset voltage VAINT2 may be output in the reset period S6.

In one or more embodiments of the present disclosure, under the control of the voltage controller VC, the voltage level of the first reset voltage VAINT1 may change. For example, under the control of the voltage controller VC, the voltage level of the second reset voltage VAINT2 in the second reset period S6-2 may be lower than the voltage level of the first reset voltage VAINT1 in the first reset period S6-1. Accordingly, a stronger reverse bias may be applied between the first electrodes EL1 and the second electrode EL2 by the first reset voltage VAINT1 having a lower voltage level.

Although one or more embodiments of the present disclosure has been described for illustrative purposes, those skilled in the art will appreciate that various modifications, and substitutions are possible, without departing from the scope and spirit of the present disclosure as disclosed in the accompanying claims.

Accordingly, the technical scope of the present disclosure is not limited to the detailed description of this specification, but should be defined by the claims.

As described above, a first connection wire electrically connected to a first common layer may receive a first reset voltage, and a second connection wire electrically connected to a charge generation layer may receive a second reset voltage.

A portion between the first connection wire and the charge generation layer may function as a parasitic capacitor due to the first reset voltage applied to the first common layer. Accordingly, a lateral leakage current through the first common layer or the charge generation layer may charge the parasitic capacitor, and may reduce or prevent the lateral leakage current from moving to adjacent pixels until the parasitic capacitor is charged. As a result, the display quality of an electronic device may be improved by reducing or preventing contrast distortion caused by the lateral leakage current.

Moreover, the timing of each of a first reset voltage applied to the first common layer and a second reset voltage applied to the charge generation layer may be controlled through reset transistors or a voltage controller, thereby initializing the voltages of the first common layer and the charge generation layer.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An electronic device comprising:
a base layer defining a first area, and a second area adjacent to the first area;
a circuit layer above the base layer;
first electrodes above the circuit layer and overlapping the first area;
a pixel-defining layer above the circuit layer and defining pixel openings exposing portions of the first electrodes;
a first connection wire above the pixel-defining layer and configured to receive a first reset voltage;
a second connection wire above the pixel-defining layer and configured to receive a second reset voltage;
a first common layer above the first electrodes, the first connection wire, and the pixel-defining layer;
a first light-emitting layer above the first common layer;
a charge generation layer above the first light-emitting layer and the second connection wire;
a second light-emitting layer above the charge generation layer;
a second common layer above the second light-emitting layer; and
a second electrode above the second common layer.

2. The electronic device of claim 1, wherein the first connection wire is electrically connected to the first common layer through first contact portions overlapping the first area.

3. The electronic device of claim 2, wherein the first contact portions are respectively between adjacent ones of the first electrodes in plan view.

4. The electronic device of claim 1, wherein the first connection wire is electrically connected to the first common layer through first contact portions having one part overlapping the second area, and another part overlapping the first area.

5. The electronic device of claim 1, wherein the second connection wire is electrically connected to the charge generation layer through a second contact portion overlapping the second area.

6. The electronic device of claim 1, wherein the second reset voltage is lower than the first reset voltage.

7. The electronic device of claim 1, further comprising:
a first reset transistor configured to be controlled in response to a first reset scan signal and configured to deliver the first reset voltage to the first connection wire; and
a second reset transistor configured to be controlled in response to a second reset scan signal and configured to deliver the second reset voltage to the second connection wire.

8. The electronic device of claim 7, wherein the first reset transistor and the second reset transistor are in the second area.

9. The electronic device of claim 7, wherein the first reset transistor is in the first area, and
wherein the second reset transistor is in the second area.

10. The electronic device of claim 7, wherein, in a reset period, a first active period of the first reset scan signal overlaps a second active period of the second reset scan signal.

11. The electronic device of claim 1, wherein the first connection wire is configured to receive a third reset voltage that is lower than the first reset voltage.

12. The electronic device of claim 11, further comprising:
a first reset transistor configured to be controlled in response to a first reset scan signal and configured to deliver the first reset voltage to the first connection wire;
a second reset transistor configured to be controlled in response to a second reset scan signal and configured to deliver the second reset voltage to the second connection wire; and
a third reset transistor configured to be controlled in response to a third reset scan signal and configured to deliver the third reset voltage to the first connection wire.

13. The electronic device of claim 12, wherein, in a reset period, a first active period of the first reset scan signal overlaps a second active period of the second reset scan signal, and does not overlap a third active period of the third reset scan signal.

14. The electronic device of claim 1, wherein the first reset voltage and the second reset voltage are externally provided.

15. An electronic device comprising:
a display panel defining a display area, and a non-display area adjacent to the display area, and comprising:
a base layer;
a circuit layer above the base layer;
first electrodes above the circuit layer;
a pixel-defining layer above the circuit layer and defining pixel openings exposing portions of the first electrodes;
a first connection wire above the pixel-defining layer and configured to receive a first reset voltage;
a second connection wire above the pixel-defining layer and configured to receive a second reset voltage;
a first light-emitting stack above the first electrodes, the first connection wire, and the pixel-defining layer;
a charge generation layer above the first light-emitting stack and the second connection wire;
a second light-emitting stack above the charge generation layer; and
a second electrode above the second light-emitting stack.

16. The electronic device of claim 15, wherein the first light-emitting stack comprises a first common layer and a first light-emitting layer above the first common layer,
wherein the second light-emitting stack comprises a second light-emitting layer and a second common layer above the second light-emitting layer, and
wherein the first connection wire is electrically connected to the first common layer through first contact portions.

17. The electronic device of claim 15, wherein the second connection wire is electrically connected to the charge generation layer through a second contact portion overlapping the non-display area.

18. The electronic device of claim 15, wherein the first connection wire is configured to receive a third reset voltage that is lower than the first reset voltage.

19. The electronic device of claim 18, wherein the display panel further comprises:
a first reset transistor configured to be controlled in response to a first reset scan signal and configured to deliver the first reset voltage to the first connection wire;
a second reset transistor configured to be controlled in response to a second reset scan signal and configured to deliver the second reset voltage to the second connection wire; and
a third reset transistor configured to be controlled in response to a third reset scan signal and configured to deliver the third reset voltage to the first connection wire.

20. The electronic device of claim 15, further comprising a voltage controller configured to control the first reset voltage and the second reset voltage.
